(19) United States
(12) Patent Application Publication
(10) Pub. No.: US 2010/0164501 A1
(43) Pub. Date: Jul. 1, 2010

(54) ALTERNATING CURRENT SWITCH DEVICE AND METHOD FOR THE MONITORING OR DIAGNOSIS OF THE OPERABILITY OF AN ALTERNATING CURRENT SWITCH DEVICE

(75) Inventor: Lutz Grimm, Hettenshausen (DE)

Correspondence Address: CROWELL & MORING LLP;INTELLECTUAL PROPERTY GROUP, P.O. BOX 14300, WASHINGTON, DC, 20044-4300, US

(73) Assignee: MTU AERO ENGINES GMBH, Munich (DE)

(21) Appl. No.: 12/441,127

(22) PCT Filed: Sep. 5, 2007
(86) PCT No.: PCT/DE2007/001594

§ 371 Date: Nov. 30, 2009

(30) Foreign Application Priority Data
Sep. 13, 2006 (DE) 10 2006 042 917.6
Mar. 30, 2007 (DE) 10 2007 015 337.8

(51) Int. Cl. G01R 31/327

(52) U.S. Cl. 324/415

(57) ABSTRACT

The invention relates to an alternating current switch device for the optional closure and opening of at least one electrically conducting connection, wherein this alternating current switch device has at least two parallel connected branches (10, 12, 14) for a flow of current in each case and wherein multiple switches (16, 18, 20) are provided that are each assigned to one of the branches (10, 12, 14), wherein respective electrically conducting connections can be closed and opened by means of these switches (16, 18, 20), allowing a current flow through the respective branch (10 or 12 or 14) to which this respective switch (16, 18, 20) is assigned, wherein a diagnostic device (22) is provided for determining the operability of the alternating current switch device (1).

The invention relates to an alternating current switch device as well as a method for monitoring or diagnosis of the operability of an alternating current switch device.

Alternating current switch devices as such are already known. They are used, for example, to turn electrical power supplies on or off for consumers or loads on or off. If these known alternating current switch devices malfunction or the connections for electrical currents are not actually generated and interrupted in the manner intended by the switching processes, the results can be an undesirable power supply or power disconnection. Depending upon the type of load or consumer, this may potentially have devastating consequences. Up until now malfunctions of alternating current switch devices can only be identified after extensive investigations, which are typically conducted when undesirable effects or devastating consequences occur in the region of the loads or consumers.

With this background, the invention is based on the objective of creating an alternating current switch device, which makes at least mitigating the consequences of malfunctions possible.

According to the invention, an alternating current switch device is therefore proposed for the optional closure and opening of at least one electrically conducting connection, wherein this alternating current switch device has at least two parallel connected branches for a flow of current in each case and wherein multiple switches are provided that are each assigned to one of the branches. Respective electrically conducting connections may be (optionally) closed and opened by means of these switches, allowing a current flow through the respective branch to which this respective switch is assigned. The alternating current switch device furthermore has a diagnostic device for determining the operability of the alternating current switch device.

The alternating current switch device is preferably an alternating current switch device of an aircraft engine, and in particular an alternating current switch device of a power management module of an aircraft engine.

It is noted that the applicant is reserving protection for a power management module, particularly the power management module of an aircraft engine, which features an inventive alternating current switch device. Moreover, the applicant is reserving protection for an aircraft engine with an inventive alternating current switch device or for an aircraft engine with a power management module which features an inventive alternating current switch device or cooperates with such an alternating current switch device. The applicant also reserves the right to direct claims to embodiments or further developments of this type.

The switches, which are switchable contacts for example, may be embodied electronically or electromechanically for example.

It must be noted that in the advantageous embodiment, the number of windings as well as the winding direction are coordinated or selected so that the branch in which there is a malfunction is clearly identifiable on the basis of the magnetic flux in the magnetic core; this can be in the case of two branches connected in parallel, or in the case of three branches connected in parallel, or in the case of four branches connected in parallel, or in the case of five branches connected in parallel, or in the case of more than five branches connected in parallel.

Moreover, according to the invention, a method for monitoring or diagnosis of the operability of an alternating current switch device is, in which the magnetic flux prevailing in the magnetic core or at least a characteristic value that is a function of this magnetic flux is checked or monitored. If the magnetic flux or the characteristic value that is a function of this magnetic flux deviates from a predetermined value, e.g., “null,” it is established that there is a malfunction of the alternating current switch device. The method is preferably used for monitoring or diagnosis of the operability of an alternating current switch device of an aircraft engine, and in particular of an alternating current switch device of a power management module of an aircraft engine.

In the following, exemplary embodiments of the invention will now be described in greater detail. However, the invention is not meant to be restricted hereby to these exemplary embodiments so that further modifications also fall under the invention. The drawings show:

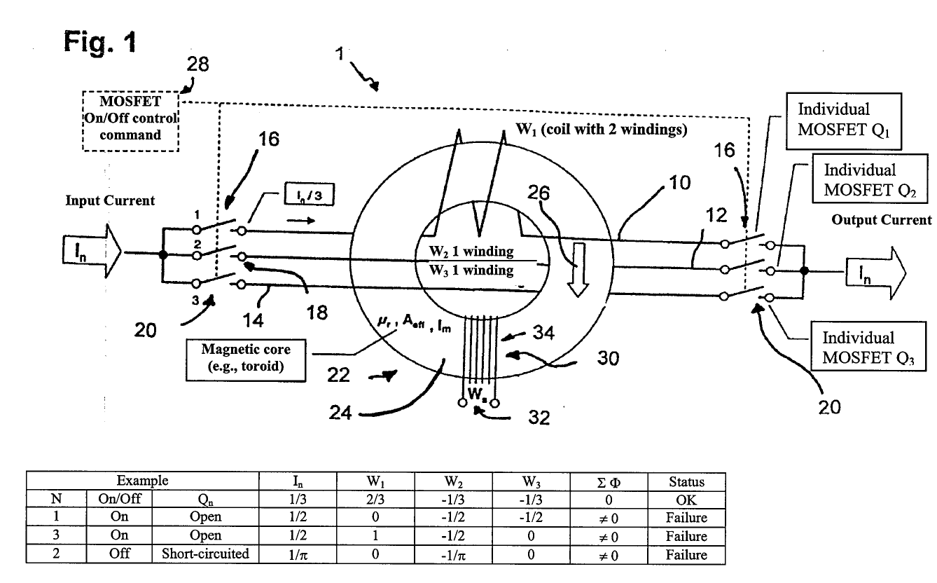

FIG. 1 a schematic view of a first exemplary embodiment of an inventive alternating current switch device;

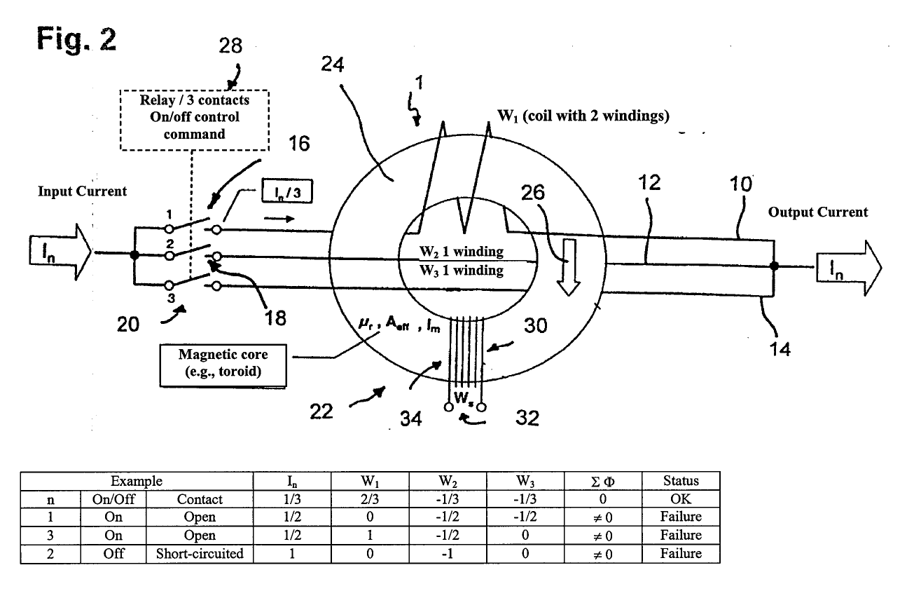

FIG. 2 a schematic view of a second exemplary embodiment of an inventive alternating current switch device; and

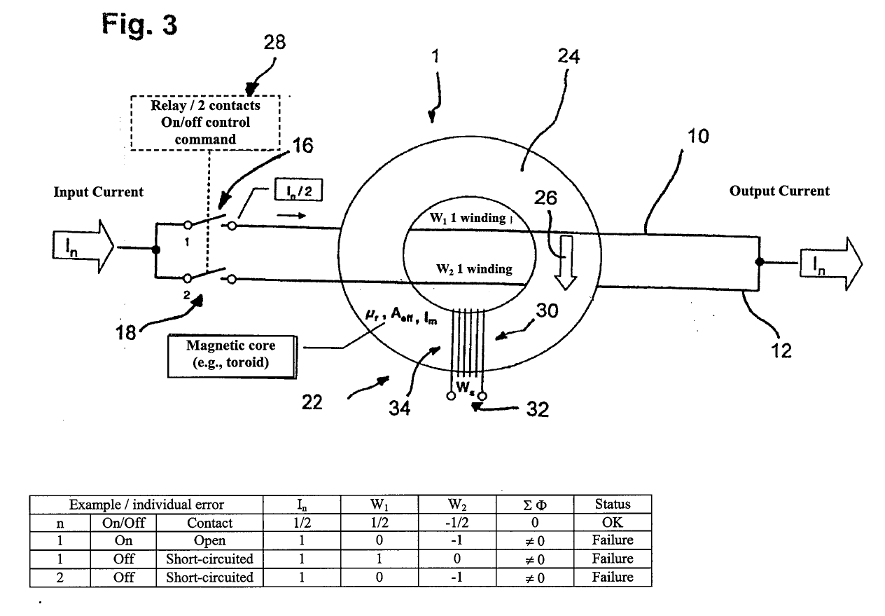

FIG. 3 a schematic view of a third exemplary embodiment of an inventive alternating current switch device.

FIG. 1 through FIG. 3 show schematic representations of three examples of an exemplary inventive alternating current switch device 1 for the optional closure and opening of at least one electrically conducting connection.

This alternating current switch device 1 has at least two branches 10, 12, 14 connected in parallel (three in each of FIGS. 1 and 2 and two in FIG. 3) for a flow of current in each case. Several (electrical) contacts or switches 16, 18, 20 are provided that are each assigned to one of the respective branches 10, 12, 14, wherein the respective electrically conducting connection can be closed and opened by means of these switches 16, 18, 20, allowing a current flow through the respective branch 10, 12, 14 to which this respective switch 16 or 18 or 20 is assigned.

As can be seen easily, during operation with at least a partially closed alternating current switch device 1, an electrical current Iₙ flows, which divides itself between the closed branches 10 or 12 or 14 or those branches 10 or 12 or 14 that are closed, and then merges again on the output side. This current Iₙ divides itself then at least reciprocally to the number of closed branches that are operable with respect to current transmission, as long as the switches 16 and/or 18 and/or 20 are closed.

Furthermore, a diagnostic device 22 is provided for determining the operability of the alternating current switch device 1. This diagnostic device 22 has a magnetic core 24, which is embodied for example as a magnetic ring core 24. Wound around this magnetic core 24 are the branches 10, 12, 14 or electrical lines or conductors of these branches 10, 12, 14—for the sake of simplicity they will be referred to as branches 10, 12, 14 in this disclosure. This is so that each of the branches 10, 12, 14 are wound around this magnet core 24 with a respective number of windings assigned to this respective branch 10 or 12 or 14 as well as a respective winding direction assigned to this respective branch 10 or 12 or 14, so that by means of this respective branch 10 or 12 or 14 a magnetic flux is always generated in the magnetic core 24 when electrical current flows through the respective branch 10 or 12 or 14.

In this case, the respective winding direction the respective number of windings of the different branches 10 or 12 or 14 are coordinated with one another in such a way that the magnetic flux in the magnetic core 24 assumes a predetermined value when the operability of the alternating current switch device 1 is a given and the switches 16, 18, 20 are each closed and an electrical (alternating) voltage is applied to the alternating current switch device 1.

In the case of the embodiment in FIG. 1, the branch 10 is wound around the magnetic core 24 with two windings and the branches 12 and 14 each have one winding (shown respectively in a simplified form for the sake of better clarity); the winding direction in the case of the branch 10 is opposite here from the winding direction of branches 12 and 14 in each case.

Just like the embodiment in FIG. 1, in the case of the embodiment in FIG. 2, the branch 10 is wound around the magnetic core 24 with two windings and the branches 12 and 14 each have one winding (shown respectively in a simplified form for the sake of better clarity); the winding direction in the case of branch 10 is opposite from the winding direction of branches 12 and 14 in each case.

In the case of the embodiment in FIG. 3, the branch 10 and the branch 12 are each wound around the magnetic core 24 with one winding (shown respectively in a simplified form for the sake of better clarity), whereby the winding direction of the branch 10 is opposite from the winding direction of the branch 12.

The (respective) entire magnetic flux in the wound core 24 is denoted schematically in the figures by the arrow 26.

It must be noted that in the tables in FIGS. 1 through 3, the winding number W₁, the current strength I₁ and the value n=1 relate to branch 10; winding number W₂, the current strength I₂ and the value n=2 relate to branch 12; and the winding number W₃, the current strength I₃ and the value n=3 relate to branch 14.

Furthermore, a control device 28 is provided for activating or for connecting the contacts or switches 16, 18, 20. The control device 28 is in particular such that it can simultaneously activate the contacts or switches 16, 18, 20 to respectively open or respectively close.

The addressed branches that are connected in parallel (i.e., in the case of the embodiments in FIGS. 1 and 2, branches 10, 12, 14 and, in the case of the embodiment in FIG. 3, branches 10, 12) are coordinated in terms of their given winding direction with respect to the magnetic core 24 as well as the number of windings in this regard with one another in such a way that the magnetic flux in the magnetic core 24 assumes a predetermined value or precisely one predetermined value when the operability of the alternating current switch device 1 is a given and the switches 16, 18, 20 are respectively closed.

In principle, this may be so that this value is a predetermined value deviating from “null”. However, in the three exemplary embodiments in accordance with the figures, this coordination is such that this predetermined value for the magnetic flux is “null”. Only in an error-free case (and with applied electrical (alternating) voltage and a closed or correspondingly activated alternating current switch device 1) will this magnetic flux of “null” adjust in the magnetic core 24, so that when a value of the magnetic flux deviating from “null” is detected in the magnetic core 24, it can be concluded that a malfunction is present.

The error-free case as well as some exemplary cases with malfunctions are depicted as an example in the tables in FIGS. 1 through 3 for the respective alternating current switch device 1 there.

The respective branch number is shown in the first column beneath “n”; the second column indicates (beneath “On/Off') whether the switches 16, 18, 20 are activated such that they are closed or should be (=on), or such that they are open or should be open. The third column indicates beneath “Contact” or beneath “Qₙ” whether the corresponding branch 10, 12, 14 or the corresponding switches 16, 18, 20 are actually open or short-circuited; the case “actually closed” is not depicted since these areas of the tables only represent faults (also see the last columns of each of the tables). The branch or branches 10, 12, 14, which are not indicated in the first column (or the associated switches 16, 18, 20), should be fully operational in this case and be in the target state indicated in the second column. The fourth column indicates the portion of the electric current Iₙ (i.e., the portion of the electrical current flowing into and out of the alternating current switch device 1), which in each case flows through the branches 10 or 12 or 14 through which current is flowing (and namely standardized with respect to Iₙ). The fifth through seventh columns of the tables shown in FIGS. 1 and 2 and the fifth and sixth columns of the table shown in FIG. 3, show the respective magnetic voltages produced by the affected branch 10, 12, 14 in the magnetic core 24 from the electric current I₁, I₂, I₃ flowing through the affected branch 10, 12, (14) with the number of windings W₁, W₂, W₃, whereby the index 1 relates to the branch 10, the index 2 relates to the branch 12 and the index 3 relates to the branch 14 (the latter allocation also applies to the branch numbers in the first column). The second column from the right in the figures lists the total magnetic flux in the magnetic core 24 or the total of the magnetic fluxes in the magnetic core 24 produced by the individual branches 10, 12, 14, and the right column indicates the status or whether operability is a given (=OK) or not (=Fail). This column also shows that when the total magnetic flux (ΣΦ) or the total (ΣΦ) of the individual fluxes is equal to “null”, the operability of the alternating current switch device 1 is a given or is assessed as a given, and when the total magnetic flux (ΣΦ) or the total (ΣΦ) of the individual magnetic fluxes is not equal to “null”, operability of the alternating current switch device 1 is not a given or is not assessed as a given.

The third to the last column of the second row of the tables in FIGS. 1 through 3 respectively represent the case that the alternating current switch device 1 is not malfunctioning or has electrical (alternating) voltage applied and an electrical current is flowing via all branches 10, 12, 14.

Rows 2 and 3 from the table in FIG. 1 are explained in more detail as an example:

Since in the case of row 2, the operability is a given, which is also shown by the last column of this row, an electric current flows through each of the three branches 10, 12, 14, and namely respectively ⅓ of the total current Iₙ(t). The application of Ampère's law taking the winding direction of the magnetic sources w₁*I₁(t), w₂*I₂(t), w₃*I₃(t), w_{S}*I_{S}(t) into consideration in the detection device 30 for the detection of the magnetic flux 26 flowing in the magnetic core 24 results in:

w₁*I₁(t)−w₂*I₂(t)−w₃*I₃(t)+w_{S}*I_{S}(t)=Rₘ*Φ(t)

With the reluctance

$$: {R}_{m} = \frac{{I}_{m}}{μ * {A}_{eff}}$$

of the magnetic core, whereby

Iₘ=average magnetic path length

μ=(μ₀*μᵣ) permeability

A_{eff}=effective core cross section

and with I_{S}(t)=0 (winding open) the following interrelationship:

$$\frac{{I}_{n} ( t )}{{R}_{m}} * ( 2 * \frac{1}{3} - 1 * \frac{1}{3} - 1 * \frac{1}{3} + {w}_{s} * \frac{0}{{I}_{n} ( t )} ) = \frac{{I}_{n} ( t )}{{R}_{m}} * ( 0 ) = 0 = Φ ( t )$$

The voltage of the signal device 32 arising on the secondary winding 34 is then also 0 according to Faraday's law:

$${U}_{S} ( t ) = {w}_{s} * ( \frac{d}{d t} Φ ( t ) )$$

It must be noted that the variables w₁, w₂ and w₃ are indicated respectively in a simplified manner in the corresponding columns in row 1. This produces, therefore, a value of 0 for the resulting magnetic flux Φ(t) in the magnetic core 24, as indicated in the next to the last column of row 2. Because in this case the criteria Φ(t)=0 applies for the status without a malfunction, precisely this is noted in the last column of row 2.

Because the branch 10 is interrupted, the electrical current is I₁(t)=0 and the following is produced for the resulting magnetic flux 26:

$$\frac{{I}_{n} ( t )}{{R}_{m}} * ( 2 * 0 - 1 * \frac{1}{2} - 1 * \frac{1}{2} + {w}_{s} * \frac{0}{{I}_{n} ( t )} ) = \frac{{I}_{n} ( t )}{{R}_{m}} * ( - 1 ) = Φ ( t ) \neq 0$$

The voltage of the signal device 32 arising on the secondary winding 34 is now as follows according to Faraday's law:

$${U}_{S} ( t ) = {w}_{s} * ( \frac{d}{d t} Φ ( t ) ) \neq 0 ,$$

i.e., nonzero. Consequently, an error is indicated in this case.

It must be noted that related to the short circuit, the value of 1/n is to be attributed to the one-way rectifier effect (MOSFET inherent diode of the non-short-circuited MOSFET of the observed branch).

Moreover, the diagnostic device 22 features a detection device 30 for detecting the magnetic flux flowing in the core 24, as well as a signal device 32 for indicating malfunctions and/or the status that there is no malfunction. According to the embodiments depicted in the figures, a secondary winding 34, which is wound around the magnetic core 24, is part of both the detection device 30 as well as the signal device 32.

In the case of the embodiment in FIG. 1, the switches 10, 12, 16 are formed by MOSFETs (=metal oxide semiconductor field effect transistors). Such an embodiment with MOSFETs is shown as an example in FIG. 1 with three branches 10, 12, 14 connected in parallel.

In the case of the embodiments in FIGS. 2 and 3, the switches 10, 12, 16 are formed by relays. Such an embodiment with relays is shown as an example in FIG. 2 with three branches 10, 12, 14 connected in parallel and as an example in FIG. 3 with two branches 10, 12, 14 connected in parallel.

As was shown on the basis of FIGS. 1 through 3, an overall status of a statically activated “alternating current switch” is created, which has n parallel connected contacts or branches or which is comprised of n parallel connected contacts or branches, wherein n is a natural number.

The magnetic flux in the magnetic core 24, according to the exemplary embodiments with given operability, is compensated for by a skilled selection of the winding direction as well as the number of windings of the involved parallel current branches. In the non-compensated case, an “error signal” is generated at the secondary winding. An alternative embodiment may also provide that the system not be coordinated for the compensated case or the case in which the magnetic flux is equal to null, rather for a magnetic flux that is not equal to null.

As the exemplary embodiments in particular make clear, the invention establishes the basis for a plurality of advantages.

Thus, a very simple, robust and cost-effective possibility for potential-free error detection is rendered possible. Moreover, an increase in operating safety as well as reliability is made possible through averting or reducing damage particularly in the case of critical applications. Furthermore, it becomes possible to isolate or localize errors in more complex systems, which may lead, in turn, to more customer-friendly systems. Besides, it becomes possible to avoid a false alarm in the case of external supply voltage interruptions. When using mechanically actuated switches or contacts, such as relays or contactors for example, wear and tear of these switches or contacts may identify a malfunction caused by this.

According to an inventive further development, the magnetic flux in the, or in a, magnetic core is compensated for by the skilled selection of the winding direction as well as the number of windings of the involved parallel current branch. In doing so, it can be provided that an “error signal” be generated at the second winding in a non-compensated case.

1. Alternating current switch device for the optional closure and opening of at least one electrically conducting connection, wherein this alternating current switch device has at least two parallel connected branches (10, 12, 14) for a flow of current in each case and wherein multiple switches (16, 18, 20) are provided that are each assigned to one of the branches (10, 12, 14), wherein respective electrically conducting connections can be closed and opened by means of these switches (16, 18, 20), allowing a current flow through the respective branch (10 or 12 or 14) to which this respective switch (16, 18, 20) is assigned,
characterized in that
a diagnostic device (22) is provided for determining the operability of the alternating current switch device (1).

2. Alternating current switch device according to claim 1, characterized in that the diagnostic device (22) has a magnetic core (24) and each of the branches (10, 12, 14) is wound with a respective number of windings assigned to this respective branch (10 or 12 or 14) as well as a respective winding direction assigned to this respective branch (10 or 12 or 14) around said magnetic core (24) so that a magnetic flux is generated in the magnetic core (24) in each case by means of this respective branch (10 or 12 or 14) when an electrical current flows through the respective branch (10 or 12 or 14), wherein furthermore the diagnostic device (22) features a detection device (30) for detecting the magnetic flux flowing in the core (24) or cooperates with such a detection device (30).

3. Alternating current switch device according to claim 2, characterized in that the respective winding direction and the number of windings of the various branches (10 or 12 or 14) are coordinated with one another in such a way that the magnetic flux in the magnetic core (24) assumes a predetermined value when the operability of the alternating current switch device (1) is a given and the switches (16, 18, 20) are each closed.

4. Alternating current switch device according to claim 3, characterized in that this predetermined value is a function of the current strength actively flowing through the alternating current switch device (1).

5. Alternating current switch device according to claim 3, characterized in that this predetermined value is always “null,” and namely in particular independent of the current strength actively flowing though the alternating current switch device (1).

6. Alternating current switch device according to one of the preceding claims, characterized in that the diagnostic device (22) has a signal device (32) for generating an error signal when a malfunction of the alternating current switch device (1) is detected, or said diagnostic device cooperates with such a signal device (32).

7. Alternating current switch device according to claim 6, characterized in that this signal device (32) has a secondary winding (34) wound around the magnetic core (24).

8. Alternating current switch device according to one of the preceding claims, characterized in that the number of windings as well as the winding direction of the various branches (10, 12, 14) are coordinated with one another in such a way that, at least in the case of known current strength flowing through the alternating current switch device (1), it can be clearly determined on the basis of the magnetic flux in the magnetic core (24) whether and in which of the branches (10, 12, 14) with its assigned switch (16, 18, 20) there is a malfunction.

9. Method for monitoring or diagnosis of the operability of an alternating current switch device (1) embodied in particular in accordance with one of the preceding claims comprising the following steps:
Checking or monitoring the magnetic flux prevailing in the magnetic core (24), or a characteristic value that is a function of this magnetic flux;
Ascertaining that there is a malfunction of the alternating current switch device (1) when the magnetic flux or the characteristic value that is a function of this magnetic characteristic value deviates from a predetermined value.

10. Method according to claim 9, characterized in that the predetermined value is such that it indicates a compensation for the magnetic fluxes prevailing in the magnetic core (24) produced by means of the branches (10, 12, 14).
